(19) United States
(12) Patent Application Publication
(10) Pub. No.: US 2016/0087590 A1
(43) Pub. Date: Mar. 24, 2016

(54) Tunable Envelope Tracking

(71) Applicants: Paolo Menegoli, San Jose, CA (US); Fabio Alessio Marino, San Diego, CA (US)

(72) Inventors: Paolo Menegoli, San Jose, CA (US); Fabio Alessio Marino, San Diego, CA (US)

(73) Assignee: ETA Semiconductor Inc., San Jose, CA (US)

(21) Appl. No.: 14/948,302

(22) Filed: Nov. 21, 2015

Related U.S. Application Data
(63) Continuation-in-part of application No. 14/664,878, filed on Mar. 22, 2015.
Application No. 14/664,878 is a continuation-in-part of application No. 14/456,184, filed on Aug. 11, 2014, now Pat. No. 9,214,512.
Application No. 14/456,184 is a continuation-in-part of application No. 13/888,368, filed on May 7, 2013, now Pat. No. 8,803,288.
Application No. 13/888,368 is a continuation-in-part of application No. 13/068,161, filed on May 5, 2011, now Pat. No. 8,498,094.
(60) Provisional application No. 61/709,907, filed on Oct. 4, 2012.
(60) Provisional application No. 61/644,070, filed on May 8, 2012.
(60) Provisional application No. 61/772,461, filed on Mar. 4, 2013.
(60) Provisional application No. 61/974,951, filed on Apr. 3, 2014.

(51) Int. Cl. H03F 1/02; H03F 3/21; H03F 3/19

(52) U.S. Cl. CPC H03F 1/0227; H03F 3/19; H03F 3/21; H03F 2200/102; H03F 2200/451

(57) ABSTRACT

A novel method to provide power management to a radio frequency amplifier is described. The method makes use of a DC-AC resonant switching power converter, a resonant tunable network and a rectifier to track the envelope signal of a radio amplifier system. This system provides a fast, efficient and clean supply to the radio frequency amplifier. The resonant power converter may be implemented with a class E inverter. The resonant power converter may be operated efficiently by switching at zero voltage switching or zero current switching. By operating the resonant switching power converter at the same frequency of the radio frequency amplifier, the spectrum of the power converter is immune from undesired harmonics while meeting the bandwidth requirement. By adaptively tuning the tunable resonant network, the output voltage of the rectifier is controlled to track the envelope signal.

The present application is a continuation in part of the regular patent application U.S. Ser. No. 14/664,878 entitled “Multiple Control Transcap Variable Capacitor”, filed by the same applicants on Mar. 22, 2015. Patent application U.S. Ser. No. 14/664,878US is a continuation in part of the regular patent application Ser. No. 14/456,184 entitled “Three Terminal Variable Capacitor”, filed by the same applicants on Aug. 11, 2014. Patent application U.S. Pat. No. 14/664,878 claims priority also from U.S. Provisional Patent Application U.S. 61/974,951 entitled “Variable Capacitor Circuit Applications”, filed by the same applicants on Apr. 3, 2014. Patent Application U.S. Ser. No. 14/456,184 is a continuation in part of the regular patent application U.S. Ser. No. 13/888,368 entitled “Analog Transcap Device” (now patent U.S. Pat. No. 8,803,288), filed by the same applicants on May. 7, 2013. Patent application U.S. Ser. No. 13/888,368 is a continuation in part of the regular patent application U.S. Ser. No. 13/068,161 entitled “Semiconductor Variable Capacitor” (now patent U.S. Pat. No. 8,498,094), filed on May 5, 2011. Furthermore, U.S. Ser. No. 13/888,368 claims priority also from the following U.S. Provisional Patent Applications: U.S. 61/644,070 for “Semiconductor controllable capacitor” filed on May 8, 2012, U.S. 61/709,907 for “Transcap Semiconductor variable capacitor” filed on Oct. 4, 2012, U.S. 61/772,461 for “Variable Capacitor Circuit Applications” filed on Mar. 4, 2013.

### BACKGROUND OF THE INVENTION

1. Field of the Invention

The present invention is in the field of envelope tracking systems. The present invention is further in the field of power amplifiers and methods for providing adaptive power supply to radio frequency power amplifiers in order to improve the overall efficiency of the system. The present invention is further in the field of switching power converters. The present invention is further in the field of resonant switching power converters. The implementation is not limited to a specific technology, and applies to either the invention as an individual component or to inclusion of the present invention within larger systems which may be combined into larger integrated circuits.

2. Brief Description of Related Art

Business and consumers use a wide array of wireless devices, including cellular phones, wireless local area network devices, global positioning system devices, wireless modems, wireless wearable devices and others.

The increased demand for wireless communication and other mobile devices has created a corresponding growth and demand for higher efficiency of operation for such devices. Generally speaking a growing number of components for such wireless devices are being fabricated and produced as part of complex integrated circuit systems. Battery life has become a very important aspect for such devices. In order to maximize battery life more emphasis has been placed on minimizing the power consumption and power dissipation of these wireless devices.

One of the largest power consumers in a radio frequency transmitter of a wireless communication device is the radio frequency (RF) power amplifier (PA). Therefore many attempts and studies have been performed to reduce the power consumption of the RFPAs. Conventional approaches to improve the efficiency of the RFPAs include envelope elimination and restoration (EER). This technique uses high efficiency non linear power amplifiers, such as Class C PAs, instead of low efficiency linear PAs such as Class A PAs. However if the power supply of these PAs requires bandwidths of several MHz or higher, instead of DC or low frequency envelopes, EER does not provide the adequate solution.

Nowadays many cell phones and other portable communication devices use higher order modulation schemes with amplitude components, in addition to phase components, therefore linear PAs are used in these systems. Therefore EER techniques cannot be utilized to improve efficiency. However generally linear PAs are not very efficient, therefore efficiency improvements are desirable for these components, without degrading their high bandwidth.

Several techniques have been implemented, like the Doherty approach, where a switching power amplifier is used in combination with a linear amplifier to provide a high bandwidth supply to the linear RF PAs. Generally in these implementations of adaptive envelope tracking systems, the switching power converter tracks the low frequency higher power components of the envelope signal, while the linear amplifier tracks the higher frequency and lower power components.

However all these techniques suffer from one major drawback. The switching amplifier introduces harmonics in the output of the envelope tracking amplifier that can be injected in the RF amplifier and therefore in the signal to the antenna. If and when this occurs the transmitted signal presents undesired frequency components. These undesired harmonics are generally due to the switching action of the switching power converter and are generally very prominent at two or more main frequencies. One of the undesired frequencies is the high frequency generated by the fast turn on and off of the power switches, but this could be somewhat attenuated or filtered.

The second component of the undesired frequency is the switching frequency of the switching power converter because that is reflected in the output ripple of the envelope tracking amplifier and it is very difficult to filter out. This harmonic could therefore appear at the output of the RF transmitter. Another limitation of the Doherty approach is that the linear amplifier is quite inefficient.

Therefore the need to improve with respect to the existing techniques is evident. The elimination of the linear amplifier is possible only if the switching amplifier is capable to respond very quickly to the envelope variations. Today's requirements in cellular telephone applications, like in WCDMA and LTE, is to have an envelope bandwidth in excess of 40 MHz. In order to achieve these speeds switching power converters that operate at frequencies in the order of 500 MHz or higher are required. Unfortunately these frequencies make conventional switching power amplifiers very inefficient.

Therefore it is a purpose of the present invention to describe an adaptive tunable envelope tracking amplifier that combines the efficiency and large bandwidth requirements with the ones of reducing the spurious undesired harmonics injected in the RF amplifier.

### SUMMARY OF THE INVENTION

In accordance with the present invention a method to generate adaptive envelope tracking to the supply of an RF power amplifier is provided. In particular, according to one embodiment of the present invention, the utilization of a high switching frequency resonant converter is presented.

The presented method to achieve the envelope tracking, so as to vary the power supply of an RF amplifier with the same RF modulation signal (envelope) in order to maintain high efficiency for an RF transmitter, consists in modulating the output voltage of a resonant power converter by means of tuning of an impedance network with the envelope signal. A resonant power converter is a switching power converter that operates in ZVS (zero voltage switching) thus removing losses occurring at the switching transitions.

The largest contribution to low efficiency in a switching power converter is due to the switching losses and in particular to the product of voltage across the switches and current in the switches during the switching transitions. The switching transition time is generally representing a small portion of the entire period, therefore not accounting for a large efficiency loss, but if the switching frequency is high, the switching transition time becomes an important part of the period contributing to high switching losses and poor efficiency.

A resonant power converter can eliminate the largest part of these switching losses by operating in ZVS. In order for the power converter to operate in ZVS, a resonant network guarantees that the voltage at the drain terminal of the main switching transistor is null when the switching occurs. If the voltage at the drain terminal of the transistor is zero when the transistor is turning on, for example, the product of voltage across the switch and current in the switch is null. The alternative to operating in ZVS is to operate in ZCS (Zero Current Switching). The concept is similar and consist in turning on and turning off the switch when the current is null thus reducing the switching losses. Resonance occurs if the signal is an AC signal. The resonant power converter converts a DC voltage into an AC signal (inverter) and the signal is subsequently rectified by a rectifier that converts it back to a DC voltage or to a relatively low frequency varying output voltage.

The output voltage of the envelope tracking system is used to power the RF amplifier, therefore its output voltage has to be able to vary in amplitude with the frequency of the envelope signal. However it is very important that no additional spurious harmonics are introduced at the output of the rectifier because any undesired frequency component of the signal may appear at the output of the transmitter and at the transmitting antenna.

One means of achieving this spectral purity is to switch the power converter at the same frequency of the RF signal carrier (a few GHz for cell phones), but generally, at these high frequencies, it is extremely difficult to obtain high efficiency (which is the ultimate objective) and it is even more troublesome to obtain a high frequency variation of the output voltage (40 MHz) without major sources of distortion.

The proposed power converter is shown in a general block diagram on FIG. 1. Four main blocks can be identified: the class E (ZVS) power inverter 1, the tunable impedance matching network 2, the rectifier 3 and the load 4 (generally emulated by a resistor and a filter capacitor) which is the RF Power Amplifier. The amplifier 5 adaptively regulates the tunable impedance matching network in order for the output of the envelope tracking system to track the envelope signal (represented by the reference signal feeding one of the amplifier 5 inputs).

Class E inverters are generally constituted by high frequency transistors that switch at the resonant frequency. The resonant network is commonly composed of two inductors and one capacitor across the switch itself. If the resonant network is properly tuned at the switching frequency the voltage at the drain of the transistor crosses the zero voltage exactly when the transistor turns on. The ZVS point is dependent on the capacitance of the parallel capacitor and on the inductance of the inductors, but also on the load (impedance) seen by the inverter. The capacitor in parallel to the transistor could be implemented as a variable capacitor and it could be tuned to operate the inverter in ZVS independently from its load. This could be implemented by a closed loop system by means of sensing the voltage across the switch at turn on and turn off and by adjusting the value of a variable capacitor across the switch to obtain ZVS operation.

FIG. 2 shows an embodiment of the circuit of FIG. 1. It should be noticed that the circuit shown in FIG. 2 is only one of the possible implementations of the block diagram depicted in FIG. 1. The class E inverter 1 is constituted by a switch S1 (generally a fast transistor) that toggles at the desired frequency. In one of the embodiments of the present invention it is envisioned that the switch S1 operates at the same frequency of the RF power amplifier, but in other embodiments the switch could operate at any high frequency as long as it is not creating undesired harmonic content at the output of the transmitter.

The RF power amplifier can operate, depending on the specific application, at a frequency of a few GHz and in those cases the amplifier may be constituted of very fast transistors, like High Electron Mobility Transistors manufactured with III-V semiconductor materials. The present invention, in one of its embodiments, teaches to use the same type of transistor as the one used in the RF Power Amplifier, even though that is only one of the possible implementations and it does not constitute a limitation to the present invention.

The tunable network 2 is comprising passive reactive components and a variable capacitor C4, which could be implemented as a transcap component, as described in the patents U.S. Pat. No. 8,803,288, U.S. Pat. No. 8,498,094 and patent applications U.S. Ser. No. 14/664,878, U.S. Ser. No. 14/456,184, of the same authors. The variable capacitor C4 is capable of varying its capacitance depending on the voltage of its control terminal, coupled to the output of the amplifier A1 in FIG. 2. By varying the capacitance of the variable capacitor C4, the tunable network varies its impedance as seen by the source (inverter) 1 and by the load 4. Therefore by tuning the network 2 in an appropriate and adaptive way, the output voltage of the tracking amplifier can be modulated to follow the envelope signal.

The rectifier 3 is shown as a conventional half bridge rectifier, but many other rectifier's configurations and topologies can be used, for instance the rectifier could be a full bridge rectifier or a synchronous rectifier, even though operating a synchronous rectifier at high switching frequencies could not be optimum in terms of efficiency. The load 4 is represented by a resistor RPA and a capacitor filter C5. When the output voltage of the amplifier A1 described in FIG. 2 is decreased, the current to the load 4 is also decreased and so is the output voltage. Therefore when the envelope reference signal is lower, the current to the load of the RF Power Amplifier (the antenna) is reduced. The quality factor Q of the filter is quite important to have efficient systems. However Q is related to the resonant frequency, to the reactance of the resonant network and to the load resistance. Therefore the choice of the capacitor C5 may be critical to obtain fast enough output response and high efficiency.

FIG. 3 shows the simulated results in the time domain for the proposed embodiment of FIG. 2 with a 2 GHz resonating power converter whose output voltage, waveform 9, is modulated by a 10 MHz envelope signal. It can be noted that the output power, waveform 7, is at levels well in excess of 1 W and more importantly that it shows swings of almost twice the power levels, while maintaining an overall efficiency (waveform 8) fluctuating around 80%.

FIG. 4 shows the spectrum of the output voltage obtained. It can be seen, from the shown waveform 9, that only the harmonic at the frequency of the carrier, here assumed to be 2 GHz, has high amplitude levels. Therefore no undesired spurious harmonics generated by the presented envelope tracking system should be introduced and should disturb the transmitter.

This modulation of the output voltage is obtained by the modulation of the variable capacitor C4 of FIG. 2 in a continuous and analog fashion. The modulation is achieved by means of an analog feedback to replicate a sinusoidal signal at 10 MHz (reference signal) to the output voltage of the power converter. However this technique could be extended also to systems in which an array of variable capacitors is switched in digital fashion to obtain an overall variable capacitance.

Furthermore this technique may be extended also to the regulation of general resonant power converters comprising a DC-AC inverter, a matching network and a rectifier. Any such resonant power converter could be used in applications totally different from the envelope tracking, however the regulation of the output voltage or of the output current may be obtained by the modulation of the capacitance of a variable capacitor as part of a matching network or, more in general, as part of a tunable resonant network. Furthermore, in order to obtain optimum efficiency independently from the load, also a variable reactive component as part of the resonant inverter could be tuned in an adaptive way so as to guarantee ZVS operation of the DC to AC power converter independently from the impedance variations.

The circuit shown in FIG. 2 may present some appreciable delay between the timing of the tuning of the variable capacitor and the output variation in response to the tuning If this delay is present, the envelope signal may be delayed to the RF amplifier in order to compensate for the latency of the envelope tracking supply circuit. It is important to note that in some applications also a pre-distortion circuit may be required in order to maintain low distortion at the output of the envelope tracking supply.

As is clear to those skilled in the art, this basic system can be implemented in many specific ways, and the above descriptions are not meant to designate a specific implementation.

### BRIEF DESCRIPTIONS OF THE DRAWINGS

The features, objects, and advantages of the present invention will become apparent upon consideration of the following detailed description of the invention when read in conjunction with the drawings in which:

FIG. 1 shows a block diagram of an envelope tracking system according to a possible general embodiment of the present invention.

FIG. 2 shows a schematic at component level of an embodiment of FIG. 1 according to an embodiment of the present invention.

FIG. 3 shows the waveforms of the most significant voltages, power and efficiency as result of the circuit simulation of the power converter of FIG. 2 with a 10 MHz envelope signal.

FIG. 4 shows the spectrum of the output voltage of the power converter of FIG. 2 as a result of the Fast Fourier Transform of the simulation of the embodiment of FIG. 2.

### DETAILED DESCRIPTION OF SPECIFIC EMBODIMENTS

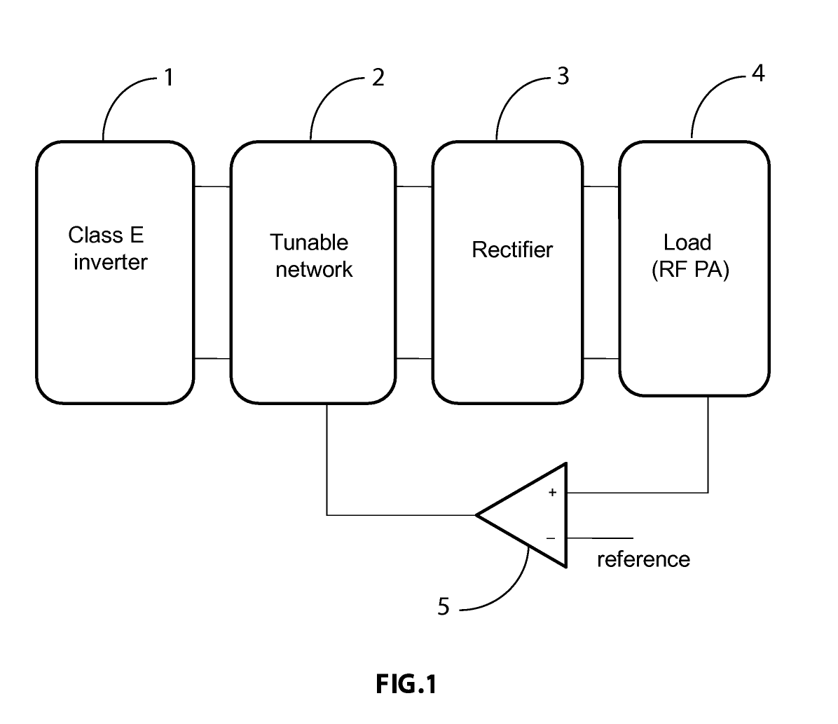

A FIG. 1

FIG. 1 shows a general block diagram of the implementation of the presented resonant envelope tracking system according to one embodiment of the present invention. The system, which could also represent a general resonant switching power converter, converts the DC signal to an AC signal, operates the control of the output power (output voltage or output current) and reconverts the AC signal back to DC, or to lower frequency AC signal, to be applied to the load. The control is adaptive depending on the input voltage, load and reference signal.

The first block 1 is represented by a DC to AC power converter, also known as inverter, and one of the most conventional configurations is the one of a class E amplifier. The class E amplifier is a resonant amplifier generally comprising a switching element and a resonant network. The switching element is commonly a high frequency FET transistor with its source coupled to a ground terminal. The resonant network coupled to the switching element is a network of reactive components, typically inductors and capacitors.

The inverter efficiency is maximized by operating the switching element in Zero Voltage Switching (ZVS). By making sure that the transistor turns on and off when the voltage at its drain is next to zero volts, the switching losses associated with its operation are virtually eliminated. The main switching losses are proportional to the switching frequency and are dependent on the product of the voltage across the transistor and the current in the transistor at the switching transition.

Generally, in a resonant network, the voltages involved at resonance are higher in amplitude, than the non resonant counterparts, however tuning the network for the switching frequency of the transistor guarantees that the losses are almost null. The resonance depends also on the load that the inverter sees, alias the impedance seen by the inverter, therefore maintaining high efficiency in the inverter may imply a separate and independent tuning of the resonant network comprised in the block 1, not shown in FIG. 1.

The block 2 describes a tunable network. Also this network is a resonant network and it may be configured as one of the many ways to implement a resonant network. This network is a matching network to match the impedance, seen looking to the left of the block 2, with the impedance seen looking to the right of block 2. By tuning this tunable network the whole circuit may be matched and therefore the maximum power to the load may be transferred. However not necessarily it is desirable to operate the matching network in matched conditions.

In fact, generally, the efficiency at the maximum power transferred to the output is poor, therefore, depending on the conditions requested by the load, it may be desirable to operate in conditions of lower output power but higher efficiency. By tuning this block 2 the output power may be controlled as desired, so as for the output voltage (or current) to follow a reference signal, indicated as one of the input signals of block 5.

Block 5 is an error amplifier and it may be implemented with an operational amplifier or a transconductance amplifier or a transimpedance amplifier. This amplifier, generates an error signal at its output that drives the tuning mechanism of block 2 thus regulating the desired output electrical parameter. When in steady state, the amplifier 5 operates with the same voltage at its inputs, thus guaranteeing that the output electrical parameter (for instance output voltage) follows the reference signal (for instance the envelope signal). The operation of the negative feedback mechanism may be implemented in many ways, without limiting the scope of the present invention, as they are generally known to anybody skilled to the art.

The block 3 represents a rectifier, a device to convert the AC signal back to a DC signal. It should be noted that the envelope signal is not necessarily a DC signal but it is a signal at a substantially lower frequency with respect to the resonant frequency of the resonant tuning network 2. Therefore the rectifier of block 3 may also convert the high frequency AC signal to a lower frequency AC signal. The rectifier may be implemented in many ways, as a half bridge rectifier, or as a full bridge rectifier and it could be implemented with diodes or with switches as a synchronous rectifier.

The block 4 represents the load. The load to an envelope tracking system is the RF amplifier itself and the system provides the regulated output voltage to track the envelope signal. However in general terms the load of the system described in FIG. 1 could comprise an output filter and it could be a resistive load, a reactive load or a complex load with both components, reactive and resistive.

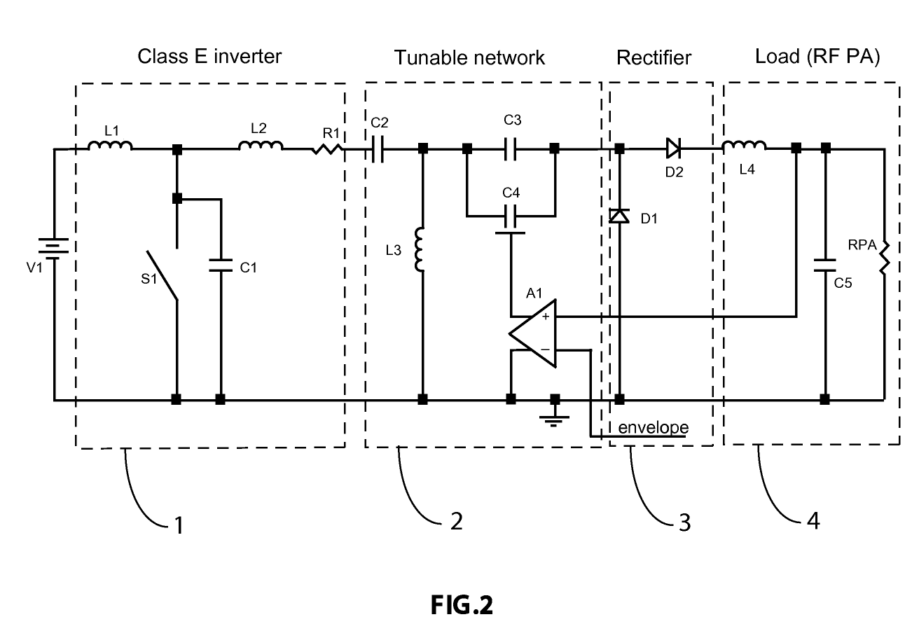

B FIG. 2

FIG. 2 shows a circuit implementation of the block diagram embodiment of FIG. 1 with the 5 main elements described above. The class E inverter 1 is constituted by the switch S1, generally implemented with a fast transistor, and the resonant network comprising the inductors L1 and L2 and the capacitor C1. The resonant network is tuned such that the voltage across the switch S1 is crossing the zero voltage point when the switch Si closes and opens. The resonant network has to be tuned to be resonant at the switching frequency of S1. The capacitor C1 could be a variable capacitor to be tuned adaptively depending on the impedance conditions at the output of the inverter 1.

The resistor R1 combines the parasitic resistance of the series components. The voltage peak across the switch S1 is larger, sometimes twice as large, than the voltage of source V1. The voltage at the output of the class E inverter 1 is transformed into an AC signal and passed to the tuning resonant network 2.

The resonant network 2 is comprising the fixed capacitors C2 and C3, the shunt inductor L3 and the variable capacitor C4. The variable capacitor C4 has three terminals and one of the three terminals is the control terminal. A voltage applied to its control terminal is determining the capacitance across the other two main terminals of the variable capacitor C4. The resonant network is a matching network and by changing the capacitance of the variable capacitor C4 the impedance of the network as seen by the inverter and as seen by the load is varied.

As this impedance is varied the power transferred to the output is also varied, as a consequence. Therefore, by controlling the capacitance of capacitor C4, the output voltage is varied and regulated. In this FIG. 2 the operation amplifier A1, described in FIG. 1 as part of block 5, is included in the tuning network 2. The operational amplifier Al, amplifying the voltage difference between the input signal indicated in FIG. 2 as “envelope” signal and the output voltage of the envelope tracking system, drives the control terminal of the variable capacitor C4. The operational amplifier A1 generally includes a compensation network not shown in FIG. 2 for sake of simplicity. The compensation network is generally included to make the control loop stable. The amplifier A1 is part of a negative feedback circuit that regulates the output voltage of the system described in FIG. 2 to track the input signal “envelope”.

As the envelope input signal increases the output of the amplifier decreases to increase the capacitance of C4 and therefore to obtain a larger power (larger capacitance level is equivalent to an impedance closer to resonance) at the output, thus obtaining higher output voltage. The tuning network described represents only one possible embodiment of many and it could be configured in many other ways as known by anyone skilled in the art, without limiting the scope of the present invention.

The rectifier is here composed of the two diodes D1 and D2 as configured in half bridge configuration. The rectifier converts the high frequency AC signal at its output into a DC signal or into a lower frequency AC signal, as is the case for the envelope signal in communication applications.

The load block 4 is here represented as an output filter (L4 and C5) and a resistor RPA. Again the load may be configured and represented in many other ways without limiting the scope of the present invention.

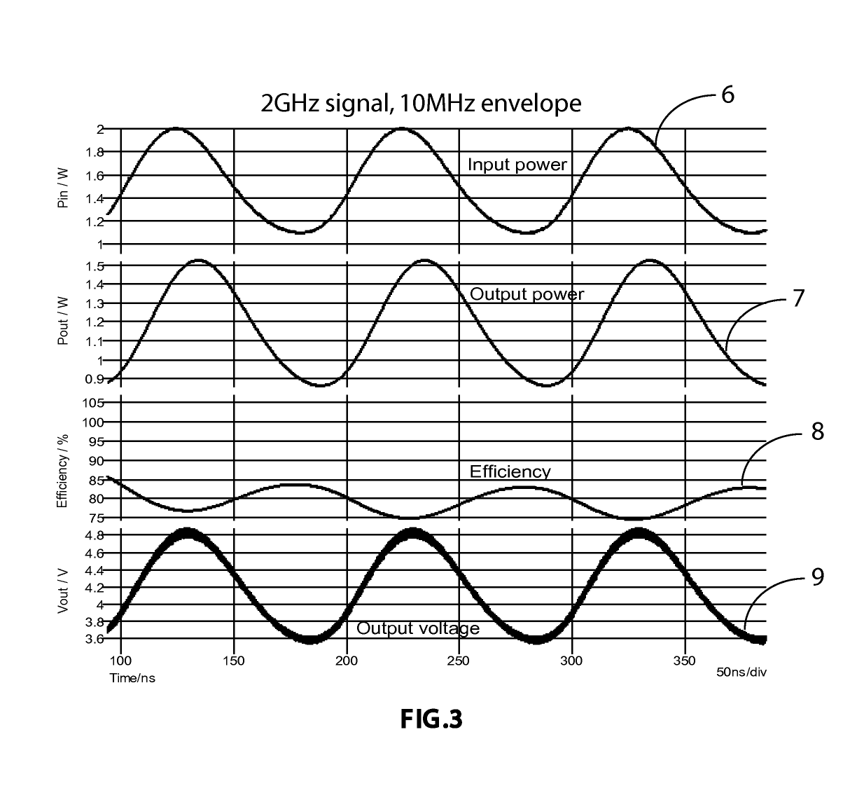

C FIG. 3

FIG. 3 shows the waveforms of the most significant voltages, of the input and output power and of the efficiency as result of the circuit simulation of the power converter of FIG. 2, with a 10 MHz sinusoidal input envelope signal. In this simulation the carrier of the signal was assumed to be 2 GHz, therefore the inverter block 1 and the tuning network 2 are operating at 2 GHz.

The waveforms 6 and 7 depict respectively the input and output power to the circuit shown in FIG. 2. Clearly the input power is larger than the output power because of the circuit losses. Both waveforms are shown in the time domain and are sinusoidal at 10 MHz. The output power is the power transferred to the load 4. The resistor RPA used in the simulation had a value of 15 Ω. It is important to notice the modulation depth of the signal, that is the amplitude of the output power signal. It can be noticed that the output power has a ratio between its positive peak and its negative peak of almost 2. This shows that the output power can be changed significantly despite the envelope signal' s high frequency.

Even more important is the fact that the output power can be changed 100% from its minimum point to its maximum level without degrading too much the efficiency of the whole system. The efficiency is represented by the waveform 8. FIG. 3 shows that it is oscillating around 80% without major valleys. The waveform 9 represents the output voltage and again it shows that the supply of the RF PA can be varied from 3.6V to almost 5V, a large range of voltage that can guarantee the Radio Frequency Power Amplifier's high efficiency depending on the envelope signal.

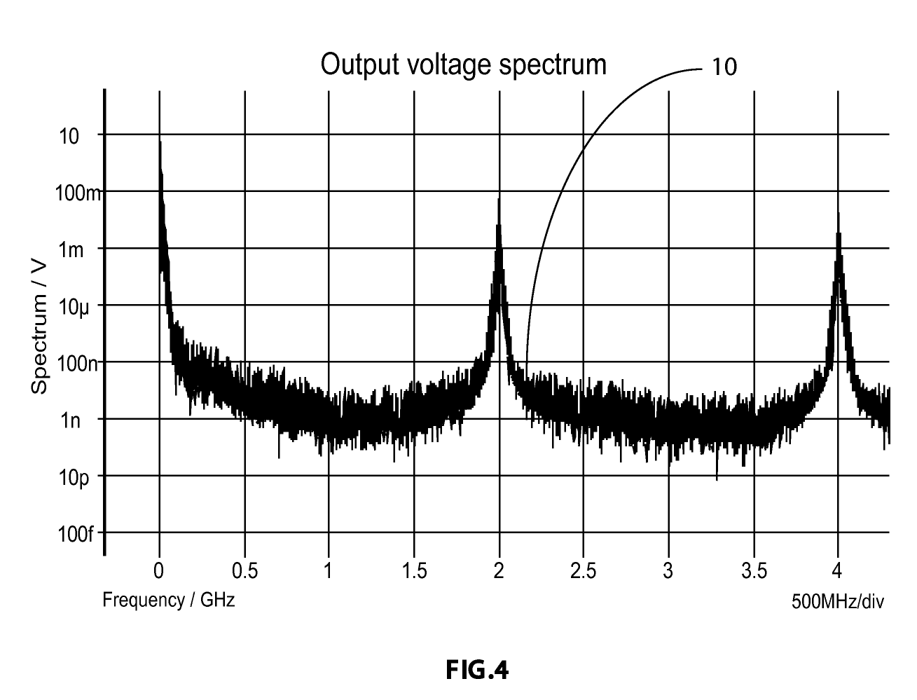

D FIG. 4

FIG. 4 shows the spectrum of the output voltage of the power converter of FIG. 2 as a result of the Fast Fourier Transform (FFT) applied to the time domain simulation results of the embodiment of FIG. 2. The FFT is shown in the frequency domain and it is indicated with waveform 10. It can be seen, from the shown waveform 10, that only the harmonic at the frequency of the carrier, here assumed to be 2 GHz, has high amplitude levels. Therefore no undesired spurious harmonics generated by the presented envelope tracking system should be occurring at the transmitter's antenna. As expected from the FFT computation, there is a mirror harmonic tone at twice the frequency of the carrier.

Although the present invention has been described above with particularity, this was merely to teach one of ordinary skill in the art how to make and use the invention. Many additional modifications will fall within the scope of the invention. Thus, the scope of the invention is defined by the claims which immediately follow.

What is claimed is:

1. An envelope tracking system to provide power management to a radio frequency power amplifier comprising:
a DC to AC resonant power converter;
a tunable resonant network comprising a tunable reactive component;
a rectifier to provide high frequency AC to low frequency AC power conversion;
an output stage comprising an output filter;
a negative feedback to control said tunable resonant network;
wherein an impedance of said tunable resonant network is modulated by tuning said tunable reactive component to control an output voltage of said envelope tracking system to track an envelope signal.

2. The envelope tracking system of claim 1, wherein said DC to AC resonant power converter is further comprising a high frequency switching component, and
wherein said DC to AC resonant power converter is adaptively tuned to guarantee zero voltage switching operation.

3. The envelope tracking system of claim 1, wherein said DC to AC resonant power converter is further comprising a high frequency switching component, and
wherein said DC to AC resonant power converter is adaptively tuned to guarantee zero current switching operation.

4. The envelope tracking system of claim 1, wherein said DC to AC resonant power converter is further comprising a high frequency switching component, and
wherein said high frequency switching component operates at substantially the same switching frequency of a carrier of said radio frequency power amplifier.

5. The envelope tracking system of claim 1, wherein said tunable reactive component is a variable capacitor.

6. The envelope tracking system of claim 1, wherein said tunable reactive component is adaptively modulated in analog fashion to control said output voltage of said envelope tracking system to track said envelope signal.

7. The envelope tracking system of claim 1, wherein said tunable reactive component is adaptively modulated in digital fashion to control said output voltage of said envelope tracking system to track said envelope signal.

8. The envelope tracking system of claim 1, wherein said tunable reactive component is a CMOS integrated variable capacitor.

9. The envelope tracking system of claim 1, wherein said negative feedback to control said tunable resonant network is comprising an operational amplifier.

10. A method for providing power management to a radio frequency power amplifier comprising:
receiving an input envelope signal;
converting a DC voltage into an AC voltage by means of a resonant power converter;
modulating an impedance of a tunable resonant network, wherein said tunable resonant network is comprising a tunable reactive component;
converting a high frequency AC voltage to a low frequency AC voltage by means of a rectifier;
filtering said low frequency AC signal by means of an output filter;
wherein said output filter is comprising an output terminal;
amplifying the voltage differential between an output voltage of said output terminal and said input envelope signal by means of an operational amplifier;
regulating said output voltage with a negative feedback to control said tunable resonant network and to said amplifier;
whereby said output voltage is tracking said input envelope signal.

11. The method of claim 10 wherein said resonant power converter is further comprising a high frequency switching component, and
wherein said resonant power converter is adaptively tuned to guarantee zero voltage switching operation.

12. The method of claim 10, wherein said resonant power converter is further comprising a high frequency switching component, and
wherein said resonant power converter is adaptively tuned to guarantee zero current switching operation.

13. The method of claim 10, wherein said resonant power converter is further comprising a high frequency switching component, and
wherein said high frequency switching component operates at substantially the same switching frequency of a carrier of said radio frequency power amplifier.

14. The method of claim 10, wherein said tunable reactive component is a variable capacitor.

15. The method of claim 10, wherein said tunable reactive component is adaptively modulated in analog fashion to control said output voltage of said rectifier to track said input envelope signal.

16. The method of claim 10, wherein said tunable reactive component is adaptively modulated in digital fashion to control said output voltage of said rectifier to track said input envelope signal.

17. The method of claim 10, wherein said low frequency AC voltage is comprising a DC voltage.

18. A tunable resonant power converter comprising:
a DC to AC resonant inverter;
a tunable resonant network comprising a tunable reactive component;
a rectifier;
an output stage comprising an output filter and a load;
a negative feedback to control said tunable resonant network;
wherein an impedance of said tunable resonant network is modulated by tuning said tunable reactive component to control an output power into said load of said tunable resonant power converter.

19. The tunable resonant power converter of claim 18, wherein said tunable reactive component is a variable capacitor.

20. The tunable resonant power converter of claim 18, wherein said DC to AC resonant inverter is comprising a variable capacitor to operate said DC to AC resonant inverter in Zero Voltage Switching conditions independently from said load.
